(19) United States
(12) Patent Application Publication
(10) Pub. No.: US 2025/0347540 A1
(43) Pub. Date: Nov. 13, 2025

(54) LAUNCH MONITOR CASE FOR RELIEVING IMPACT ON THE LAUNCH MONITOR

(71) Applicant: Vieworks Co., Ltd., Anyang-si (KR)

(72) Inventor: Gwan Su LEE, Gunposi (KR)

(21) Appl. No.: 19/204,936

(22) Filed: May 12, 2025

(30) Foreign Application Priority Data
May 13, 2024 (KR) 10-2024-0062313

(51) Int. Cl. G01D 11/24; A63B 24/00; A63B 102/32

(52) U.S. Cl. CPC G01D 11/245; A63B 24/0021; A63B 2024/0028; A63B 2102/32

(57) ABSTRACT

A launch monitor case for relieving an impact applied to a launch monitor according to an embodiment may include a damping member configured to reduce transmission of the impact into the inside of the launch monitor, an outer housing fastened to the damping member at least one location and pushed in a direction of the impact when the impact is applied to the fastened location to relieve the impact, and an inner housing fitted and fixed to the damping member.

### CROSS-REFERENCE TO RELATED APPLICATION

This application claims priority to and the benefit of Korean Patent Application No. 10-2024-0062313, filed on May 13, 2024 the disclosure of which is incorporated herein by reference in its entirety.

### BACKGROUND

### 1. Field of the Invention

The technical ideas of the present disclosure relate to a launch monitor case for relieving an impact applied to a launch monitor.

### 2. Discussion of Related Art

Conventional virtual golf systems, which are widely distributed to allow golfers to enjoy golf at a low cost, measure the physical quantities related to golf clubs based on the trajectory of the golf clubs relative to balls when the golfers hit the balls, and provide the golfers with the simulation results.

These virtual golf systems may include launch monitors that collect ball launch data via cameras. The launch monitors may produce simulation results based on ball launch data. The launch monitors are located directly in front of users and may track the users' golf swings and ball trajectories.

The launch monitors, which analyze golf swings and ball trajectories through the launch monitors located in front of the users, are inevitably exposed to the impact on the balls hit by the users or the impact caused by the golf swings. Particularly, the launch monitors are composed of camera devices and circuit boards that are vulnerable to the impact and thus tend to be susceptible to damage.

Metals, which are strong materials, are used for conventional launch monitors to prevent damage to internal components. There is a drawback that launch monitors made of strong materials do not directly transmit the impact to the internal components, but absorb the impact as is, spreading the impact throughout the product, and causing the fastening between the product and the ground to be loosened.

### SUMMARY OF THE INVENTION

A launch monitor case for relieving an impact applied to a launch monitor according to an embodiment of the present disclosure includes a damping member configured to reduce transmission of the impact into the inside of the launch monitor, an outer housing fastened to the damping member at least one location and pushed in the direction of the impact when the impact is applied to the fastened location to relieve the impact, and an inner housing fitted and fixed to the damping member.

According to one embodiment, the damping member may be composed of a particle-shaped foam resin having a density of 0.018 g/cm³ to 0.26 g/cm³, and the particle-shaped foam resin may be composed of at least one of expanded polypropylene (EPP), expanded polyethylene (EPE), and expanded polyurethane (EPU).

According to one embodiment, the outer housing may be in close contact with the damping member at the fastened location, and configured to release the close contact when the impact is applied to relieve the impact.

According to one embodiment, the outer housing may include a fastening portion in which fastening is fixed by being engaged in the direction toward the inner housing of the damping member in a state in which the impact is not applied, and in the damping member, when the inner housing is mounted, a gap may be formed around a location where the fastening portion is fastened.

According to one embodiment, the outer housing may include a hook member protruding toward the damping member and fastened to the damping member, and the hook member may be configured so that, when the impact is applied to the outer housing, the damping member is compressed by the hook member to release the close contact with the damping member in the direction of the impact.

According to one embodiment, an insertion groove of a predetermined size may be formed in the damping member, the outer housing may include an insertion member having a cross-sectional area of the predetermined size that is inserted into the insertion groove when fastened to the damping member, and when a washer having a cross-sectional area greater than the size of the insertion groove is fitted onto the insertion member, the damping member is pressed against the washer and the outer housing so that the outer housing is fixed to the damping member.

According to one embodiment, the inner housing may have a protrusion formed on a surface thereof that comes into contact with the damping member, and when the inner housing is fitted into the damping member, the damping member may be compressed and fitted by the protrusion.

A method of relieving an impact applied to a launch monitor by a launch monitor case according to an embodiment of the present disclosure includes reducing transmission of the impact into an inside of the launch monitor by a damping member, and relieving the impact by being pushed in the direction of the impact by an outer housing fastened to the damping member at least one location when the impact is applied to the fastened location.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a view showing a launch monitor device according to an embodiment of the present disclosure;

FIG. 2 is a view showing a launch monitor case according to the embodiment of the present disclosure;

FIG. 3 is a view showing a method of fastening an outer housing and a damping member according to one embodiment;

FIGS. 4A and 4B are views showing the method of fastening the outer housing and the damping member for relieving an impact according to one embodiment;

FIGS. 5A and 5B are views showing a method of absorbing impact using the outer housing and the damping member when an impact is applied to the outer housing according to one embodiment;

FIGS. 6A and 6B are views showing that the outer housing is restored to its original state after absorbing an impact according to one embodiment;

FIG. 7 is a view showing a surface of an inner housing that comes into contact with the damping member according to one embodiment; and

FIGS. 8A and 8B are views showing a gasket mounted between the outer housing and the damping member according to one embodiment.

### DETAILED DESCRIPTION OF EXEMPLARY EMBODIMENTS

Specific structural or functional descriptions of the embodiments are disclosed for illustrative purposes only and may be modified and implemented in various forms. Therefore, the actual implemented form is not limited to the specific embodiments disclosed, and the scope of this specification includes modifications, equivalents, or alternatives included in the technical idea described in the embodiments.

Although the terms first or second may be used to describe various components, these terms should be interpreted as only distinguishing one component from another. For example, a first component may be named a second component, and similarly, the second component may also be named the first component.

Singular expressions include plural expressions unless the context clearly indicates otherwise. In this document, each of the phrases “A or B,” “at least one of A and B,” “at least one of A or B,” “A, B, or C,” “at least one of A, B, and C,” and “at least one of A, B, or C” can include any one of the items listed together with the corresponding phrase among those phrases or all possible combinations thereof. In this specification, it should be understood that terms such as “comprise” or “have” are intended to specify the presence of a described feature, number, step, operation, component, part, or combination thereof, but do not exclude in advance the possibility of the presence or addition of one or more other features, numbers, steps, operations, components, parts, or combinations thereof.

Hereinafter, embodiments are described in detail with reference to the attached drawings. When describing with reference to the attached drawings, the same components are denoted by the same reference numerals regardless of the drawing numbers, and redundant descriptions thereof are omitted.

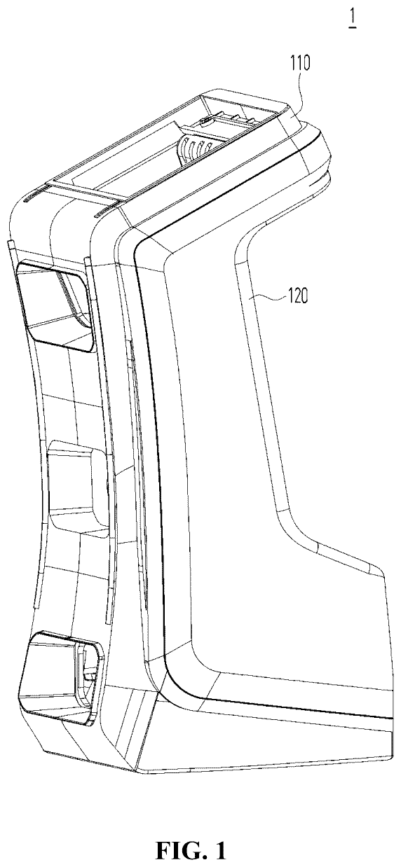

FIG. 1 is a view showing a launch monitor device according to an embodiment of the present disclosure.

Referring to FIG. 1, the launch monitor device according to the embodiment of the present disclosure may be mounted in a launch monitor case. The launch monitor case may include an outer housing 100, a damping member, and an inner housing. Only the outer housing 100 may be exposed to the outside.

The outer housing 100 may be formed by coupling a plurality of parts, and gaps between the plurality of parts that are coupled may be sealed by a sealing member. The plurality of parts may include a first outer housing 110 and a second outer housing 120. The first outer housing 110 may be disposed in a front direction, and the second outer housing 120 may be disposed in a rear direction.

The front direction may be a direction in which a user is located, and at least one camera device for tracking the trajectories of a ball and club may be mounted in the first outer housing 110. For example, three camera devices may be disposed between the first outer housing 110 and the inner housing, and the camera devices may be mounted in the inner housing and all face the user. In order to prevent the camera devices from being damaged by the ball and the club, the camera devices may be mounted in an opening portion of the first outer housing 110 that does not protrude outward but is recessed to a predetermined depth. Additionally, an opening portion through which a display panel is mounted may be formed in the first outer housing 110.

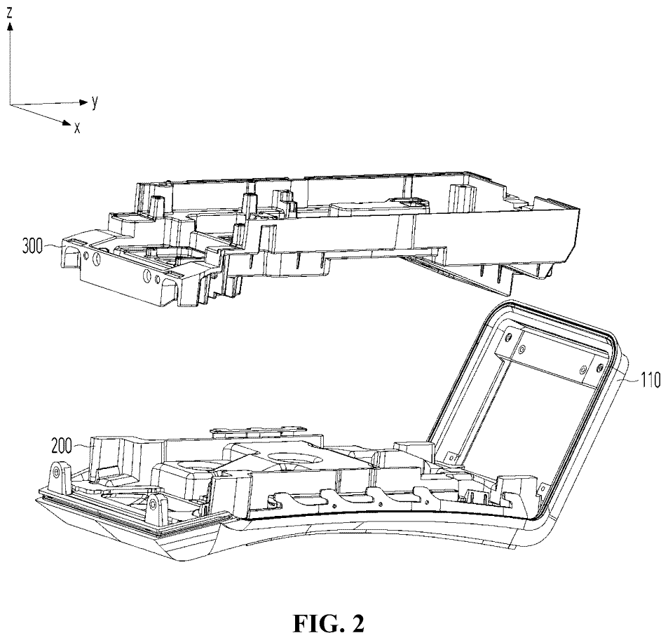

FIG. 2 is a view showing a launch monitor case according to the embodiment of the present disclosure.

Referring to FIG. 2, the launch monitor case may include the outer housing 100, a damping member 200, and an inner housing 300. The damping member 200 may be disposed between the outer housing 100 and the inner housing 300, and each of the outer housing 100 and the inner housing 300 may be fitted and fixed to the damping member 200. In this case, the outer housing 100 and the inner housing 300 may be fastened to the damping member 200 at different locations. That is, an impact applied to the outer housing 100 may not be directly transmitted to the inner housing 300, and an impact amount may be reduced through the damping member 200 and then transmitted to the inner housing 300. This prevents damage to the product by preventing an external impact from reaching main components such as a circuit board, a lens, and an image sensor inside the launch monitor case.

According to one embodiment, the damping member 200 may be fastened to the first outer housing 110 of the outer housings 100 located in the front direction, and the inner housing 300 may be fitted and fixed to an inner wall of the damping member 200. When the first outer housing 110 is fastened to the damping member 200, the fastening may be fixed by being engaged in a direction toward the inner housing 300 of the damping member 200. Referring to the embodiment of FIG. 2, the damping member 200 may be located in a +z direction of the first outer housing 110, and the damping member 200 may be inserted into the first outer housing 110. In this case, a fastening portion of the first outer housing 110 may be engaged on the surface of the damping member 200 in the +z-direction. For example, when the damping member 200 is inserted into the first outer housing 110, the fastening portion composed of a hook member may open outward due to elasticity and then close when the insertion is completed. The closed hook members may be fixed by being engaged on the surface of the damping member 200.

The inner housing 300 may be fitted and fixed to the inner wall of the damping member 200. The circuit board may be mounted in the inner housing 300 and connected to a camera device mounted in the first outer housing 110. For example, the circuit board may be located in the +z direction of the inner housing 300.

The damping member 200 may be composed of a particle-type foam resin and may have a density of 0.018 g/cm³ to 0.26 g/cm³. The particle-type foam resin may be composed of at least one of expanded polypropylene (EPP), expanded polyethylene (EPE), and expanded polyurethane (EPU). The damping member 200 used in the conventional launch monitor is composed of silicone rubber and may have a density of about 1.5 g/cm³. That is, the damping member 200 used in the conventional launch monitor may have a high density and tend to be too heavy to be used in the launch monitor.

In contrast, the damping member 200 of the present disclosure may be a low-density particle-type foam resin, enable a lightweight product, and have an excellent energy absorption effect. In addition, the damping member 200, which is a particle-type foam resin, may be easy to reuse and process, and may have excellent insulation properties.

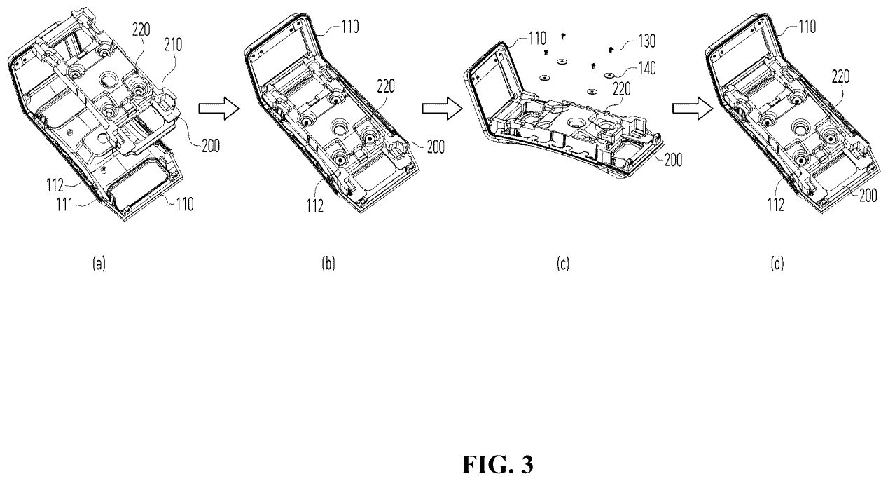

FIG. 3 is a view showing a method of fastening the outer housing 100 and the damping member 200 according to the embodiment.

Referring to FIG. 3, the first outer housing 110 may include the fastening portions for fastening with the damping member 200. For example, the fastening portions may include hook members 111 and insertion members 112. The damping member 200 may include catch grooves 210 and insertion grooves 220 that may be engaged and coupled with the fastening portions.

When the first outer housing 110 and the inner housing 300 are directly coupled, even when the damping member 200 is disposed between the first outer housing 110 and the inner housing 300, damage may occur at a boss portion where the first outer housing 110 and the inner housing 300 are connected. In addition, an impact is directly transmitted to the inner housing 300 such that the impact may be directly transmitted to internal components including the circuit board mounted on the inner housing 300. Accordingly, the first outer housing 110 and the damping member 200 of the present disclosure may be assembled in a structure that prevents an external force from being directly transmitted to the internal components.

Referring to FIGS. 3A and 3B, the hook members 111 may be disposed in an outer direction of the first outer housing 110, and may be disposed at four locations, that is, the upper left, upper right, lower left, and lower right of the first outer housing 110. The arrangement position and number of hook members 111 are not limited thereto, and may include all positions and numbers where the damping member may be fastened and firmly fixed. The catch grooves 210 in which the hook members 111 may be engaged after being inserted may be formed in the damping member 200. A thickness of the damping member 200 in a portion where the catch groove 210 is formed may correspond to a height of the hook member 111.

Referring to FIGS. 3B, 3C, and 3D, the insertion members 112 of the first outer housing 110 may be inserted into the insertion grooves 220 of the damping member 200. In this case, in order to firmly fasten the first outer housing 110 and the damping member 200, the insertion member 112 and the insertion groove 220 may be configured to have corresponding sizes and shapes. In this case, screw threads to which bolts 130 may be fastened may be formed in the insertion members 112 of the first outer housing 110.

According to one embodiment, the insertion member 112 may be fastened with the bolt 130 while being fitted into the insertion groove 220, and a washer 140 may be disposed between the insertion member 112 and the bolt 130. A size of the washer 140 may be greater than a cross-sectional area of the insertion member 112 and a size of the insertion groove 220. When the washer 140 and the bolt 130 are fastened to the insertion member 112, the insertion member 112 may be engaged by the washer 140, thereby preventing the first outer housing 110 from being detached from the damping member 200.

The fastening portion according to the embodiment of the present disclosure may be composed of only one of the hook member 111 and the insertion member 112, but more preferably, the fastening portion may be firmly fixed by catching the damping member 200 through the hook member 111 at a side surface of the first outer housing 110 and fastening the damping member 200 through the insertion member 112 at a center portion of the first outer housing 110.

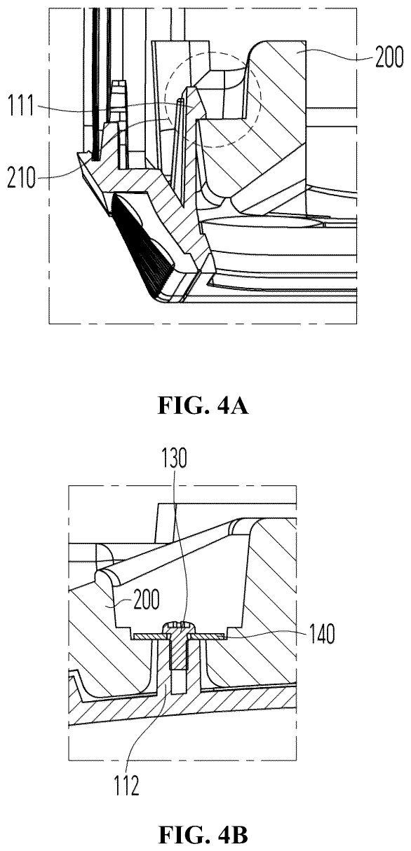

FIGS. 4A and 4B are views showing a method of fastening the outer housing 100 and the damping member 200 for relieving an impact according to one embodiment.

Referring to FIG. 4A, the hook member 111, which is one of the fastening portions, may be inserted into the catch groove 210 of the damping member 200 and then fixed across an upper end of the damping member 200. The hook member 111 may be formed on each of left and right side surfaces of the first outer housing 110, and the fastening may be fixed by pressing the damping member 200 through the hook members 111 on both side surfaces.

In this case, a predetermined margin space may be formed between the hook member 111 and the damping member. The margin space may be a space formed in a portion where the impact is applied when the first outer housing 110 and the damping member are in close contact with each other in the fastening portions. For example, on one side where the hook member 111 may be engaged on the damping member 200, the hook members 111 on both side surfaces of the first outer housing 110 and the damping member 200 may be brought into close contact with each other so that the damping member 200 is firmly fixed to the first outer housing 110 by the two hook members 111. In this case, a margin space capable of absorbing an impact may be formed between the hook member 111 to which the impact is applied and the damping member 200. One side of the hook member 111 may be located in an inward direction where the inner housing 300 is located, and the other side of the hook member 111 may be exposed to the outside and located in an outward direction where the impact is applied.

Referring to FIG. 4B, the insertion member 112, which is one of the fastening portions, may be inserted into the insertion groove 220 of the damping member 200 and then fixed by the bolt 130 and the washer 140. In this case, the size of the washer 140 may be greater than the cross-sectional area of the insertion member 112 and the size of the insertion groove 220. Therefore, when the washer 140 is fitted and fastened between the bolt 130 and the insertion member 112, the damping member 200 near the insertion groove 220 may be engaged by the washer 140, thereby preventing the first outer housing 110 from being detached from the damping member 200. In addition, the bolt 130 and the washer 140 of the present disclosure are not limited thereto and may be formed as an integrated part.

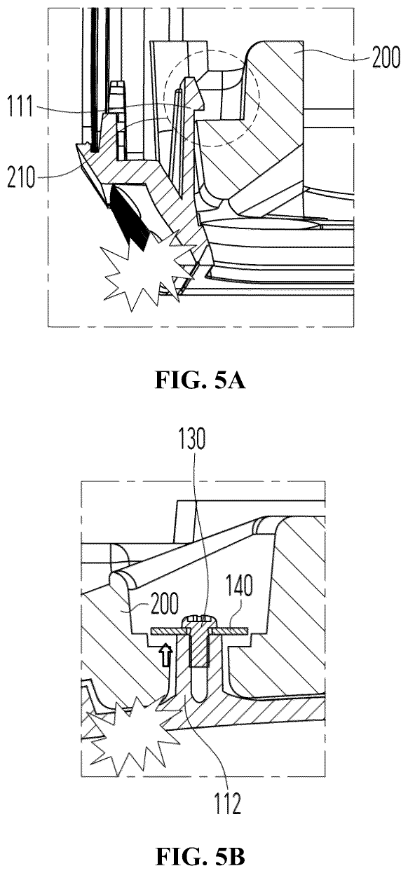

FIGS. 5A and 5B are views showing a method of absorbing impact using the outer housing and the damping member when an impact is applied to the outer housing according to one embodiment.

In the case of the conventional launch monitor, an impact could only be reduced through the damping member 200 made of a rubber material, and the focus was only on firmly fastening the outer housing 100 and the damping member 200.

In contrast, the launch monitor case of the present disclosure may not only use the damping member 200 composed of a particle-type foam resin, but also relieve the impact through the fastening portions. That is, the launch monitor case assembly structure of the present disclosure may not only firmly secure the assembly through the fastening portions, but also relieve an impact by temporarily releasing the tightly fastened configuration when an impact is applied.

Referring to FIG. 5A, when an impact is applied to the first outer housing 110 by the ball or club, the impact may be relieved by the fastening portions through which the first outer housing 110 and the damping member 200 are fastened. Specifically, although one side of the hook member 111 may move in a direction in which the inner housing 300 is located after the fastening is completed, the hook member 111 may be engaged by the damping member 200 so that the one side thereof does not move in the opposite direction. Since the other side of the hook member 111 to which the impact is applied is in partial contact with the damping member 200, but is not restrained, the other side thereof can move in the direction in which the inner housing 300 is located and in the direction opposite thereto, and thus may move relatively freely compared to the one side of the hook member 111. That is, when an impact is applied to the hook member 111, the hook member 111 may be pushed in the direction in which the inner housing 300 is located.

In addition, a margin space is formed on the other side of the hook member 111, and when an impact is applied, the other side of the hook member 111 is pushed into the margin space while one side of the hook member 111 is in close contact with the damping member 200, thereby dispersing an external force over time. When the other side of the hook member 111 is pushed into the margin space and then comes into contact with the damping member 200, the external force applied to the first outer housing 110 may be dispersed through the damping member 200.

In this case, when the other side of the hook member 111 is pushed into the margin space and compresses the damping member 200, the close contact between one side of the hook member 111 and the damping member 200 may be released and the separated state may be temporarily maintained.

Referring to FIG. 5B, when an impact is applied around the location where the insertion member 112 and the insertion groove 220 are fastened, the insertion member 112 may be pushed into the margin space and compress the damping member 200 at the location where the impact occurs. In this case, the movement of the washer 140 and the bolt 130 toward the inner housing 300 is not restricted by the damping member 200 and the first outer housing 110, and the washer 140 and the bolt 130 may be temporarily separated as much as the insertion member 112 is pushed in by the impact.

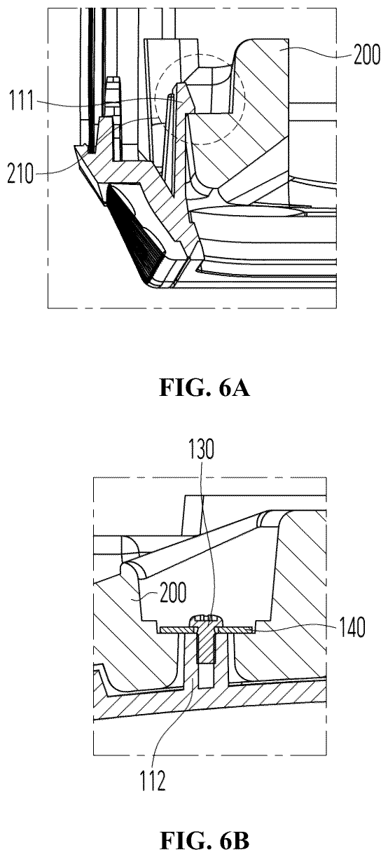

FIGS. 6A and 6B are views showing the outer housing 100 that is restored to its original state after absorbing an impact according to one embodiment.

The damping member 200 may be composed of a particle-shaped foam resin having elasticity, and the fastening portions may be pushed in a direction opposite to the direction in which the impact is applied due to the elasticity. That is, the fastening portions may move in an outward direction of the first outer housing 110.

Referring to FIG. 6A, after an impact is applied to a location near the hook member 111, the hook member 111 may be restored to its original position. For example, while one side of the hook member 111 is in close contact with the damping member 200 again, the fastening between the damping member 200 and the first outer housing 110 may be maintained. The other side of the hook member 111 may be pushed out again in the outward direction of the first outer housing 110, and a margin space of a predetermined size may be formed again between a part of the other side of the hook member 111 and the damping member 200.

Referring to FIG. 6B, as the damping member 200 is restored again to its original state, the insertion member 112 that is moved toward the inner housing 300 may be pushed outward. When the insertion member 112 is pushed outward, the washer 140 and the bolt 130 that are fixed to the insertion member 112 may be engaged in the insertion groove 220 of the damping member 200 so that the fastening between the damping member 200 and the first outer housing 110 is fixed.

According to FIGS. 4A to 6B described above, unlike the conventional launch monitor case, the fastening portions of the launch monitor case of the present disclosure may be engaged on a surface of the damping member 200 in a direction toward the inner housing 300, and the first outer housing 110 may be prevented from escaping outward from an inner direction due to the catching of the fastening portions. In this case, the damping member 200 may be configured so that gaps are formed around locations where the fastening portions are fastened, and then the fastening portions move into the gaps when an impact is applied to the fastening portions.

Therefore, unlike the conventional launch monitor case, not only is the impact relieved by the damping member 200, but the impact may also be relieved by the fastening portions through which the first outer housing 110 and the damping member 200 are fastened.

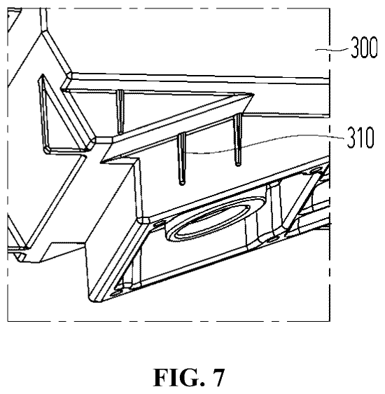

FIG. 7 is a view showing a surface of the inner housing 300 that comes into contact with the damping member according to one embodiment.

Referring to FIG. 7, at least one protrusion 310 may be formed on a surface of the inner housing 300 that comes into contact with the damping member 200. When the inner housing 300 is mounted on the damping member 200, the protrusion 310 may be fitted while pressing the damping member 200.

For example, the protrusion 310 may be a conical protrusion 310 that becomes narrower as it goes toward the damping member 200, and the cross-section of the protrusion 310 may be formed in a semicircle. That is, when the inner housing 300 is mounted on the damping member 200, a contact cross-sectional area of the protrusion 310 may become wider as the inner housing 300 is inserted into the damping member 200.

Accordingly, the inner housing 300 does not have to press the damping member 200 too much when it is first installed, and as the inner housing 300 is inserted into the damping member 200, a compressed volume of the damping member 200 may gradually increase. Therefore, during the assembly process of the launch monitor case, an installer does not have to assemble the inner housing 300 to the damping member 200 by applying an excessive force from the beginning, and may naturally mount the inner housing 300 to the damping member 200 by gradually applying a small amount of force.

However, the shape of the protrusion 310 of the present disclosure is not limited thereto, and the installer may insert the inner housing 300 into the damping member 200 with a small amount of force, and at the same time, allow the inner housing 300 to be firmly coupled to the damping member 200 by compressing the damping member 200.

In addition, since the coupling between the inner housing 300 and the damping member 200 is formed to have a flexible structure, when an impact is applied to the launch monitor case, a coupling portion may be prevented from being damaged, and the impact transmitted to the circuit board mounted on the inner housing 300 may be minimized.

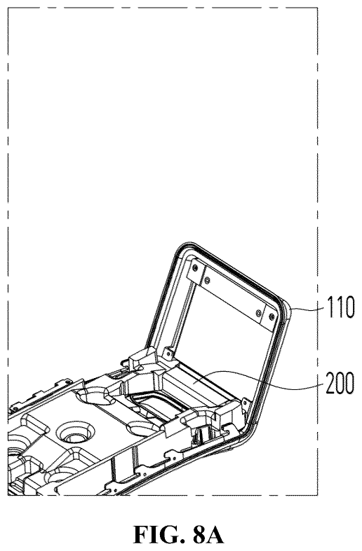

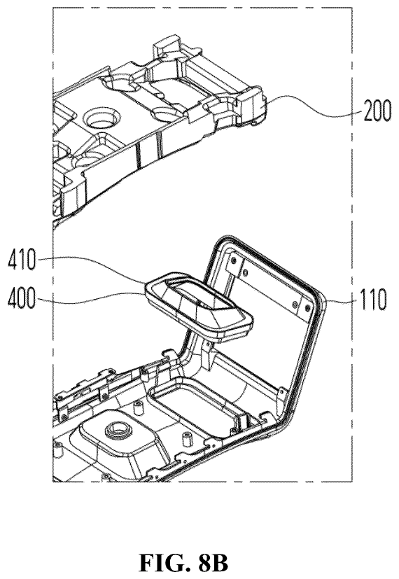

FIGS. 8A and 8B are views showing a gasket 400 mounted between the outer housing 100 and the damping member 200 according to one embodiment.

Referring to FIGS. 8A and 8B, the gasket 400 may be mounted between the damping member 200 and the first outer housing 110 at a location where the camera device is mounted on the launch monitor case. A position of the gasket 400 may be restricted by the fastening structure of the first outer housing 110 and the damping member 200. The gasket 400 may prevent the ingress of foreign substances, water, dust, etc. from entering the camera device and internal components through the first outer housing 110.

According to one embodiment, a predetermined space may be formed between the first outer housing 110 and the damping member 200 near the position where the camera device is mounted on the launch monitor case, and the gasket 400 may be disposed in the predetermined space and then compressed by the first outer housing 110 and the damping member 200. At least one protrusion 410 may be formed on a surface of the gasket 400 in a direction toward the damping member 200. The protrusion 410 may press the damping member 200, and the protrusion 410 maintains perfect sealing between the gasket 400 and the damping member 200, thereby completely preventing the entry of external foreign substances.

According to one embodiment, the gasket 400 may be composed of a flexible material that may be fixed by the first outer housing 110 and the damping member 200, and for example, a rubber material may be used. In this case, the protrusion 410 of the gasket 400 may have a higher density and strength than the damping member 200 so as to be able to compress the damping member 200. That is, the strength and density of the launch monitor case parts may be strongly configured in the order of the damping member 200, the gasket 400, and the first outer housing 110.

A launch monitor case according to the technical ideas of the present disclosure can minimize an external impact caused by a ball and a club through the structure of a damping member and an outer housing that relieves an impact, and prevent damage to the product by preventing the impact transmitted to the case from being transmitted to main internal components.

Although the embodiments have been described with limited drawings as described above, those skilled in the art can apply various technical modifications and variations based on these embodiments. For example, suitable results may be achieved even when the described techniques are performed in an order different from that of the described method, and/or components, such as the described systems, structures, devices, and circuits, are coupled or combined in a manner different from that of the described method, or are replaced or substituted by other components or equivalents.

Therefore, other implementations, other embodiments, and equivalents to the claims are also included within the scope of the claims described below.

What is claimed is:

1. A launch monitor case for relieving an impact applied to a launch monitor, the launch monitor case comprising:
a damping member configured to reduce transmission of the impact into an inside of the launch monitor;
an outer housing fastened to the damping member at least one location and pushed in the direction of the impact when the impact is applied on the fastened location to relieve the impact; and
an inner housing fitted and fixed to the damping member.

2. The launch monitor case of claim 1, wherein the damping member is composed of a particle-shaped foam resin having a density of 0.018 g/cm³ to 0.26 g/cm³, and the particle-shaped foam resin is composed of at least one of expanded polypropylene (EPP), expanded polyethylene (EPE), and expanded polyurethane (EPU).

3. The launch monitor case of claim 1, wherein the outer housing is in close contact with the damping member at the fastened location, and configured to release the close contact when the impact is applied to relieve the impact.

4. The launch monitor case of claim 3, wherein the outer housing includes a fastening portion in which fastening is fixed by being engaged in a direction toward the inner housing of the damping member in a state in which the impact is not applied, and
in the damping member, when the inner housing is mounted, a gap is formed around a location where the fastening portion is fastened.

5. The launch monitor case of claim 3, wherein the outer housing includes a hook member protruding toward the damping member and fastened to the damping member, and
the hook member is configured so that, when the impact is applied to the outer housing, the damping member is compressed by the hook member to release the close contact with the damping member in the direction of the impact.

6. The launch monitor case of claim 3, wherein an insertion groove of a predetermined size is formed in the damping member,
the outer housing includes an insertion member having a cross-sectional area of the predetermined size that is inserted into the insertion groove when fastened to the damping member, and
when a washer having a cross-sectional area greater than the size of the insertion groove is fitted onto the insertion member, the damping member is pressed against the washer and the outer housing so that the outer housing is fixed to the damping member.

7. The launch monitor case of claim 1, wherein the inner housing has a protrusion formed on a surface thereof that comes into contact with the damping member, and when the inner housing is fitted into the damping member, the damping member is compressed and fitted by the protrusion.

8. A method of relieving an impact applied to a launch monitor by a launch monitor case, the method comprising:
reducing transmission of the impact into an inside of the launch monitor by a damping member; and
relieving the impact by being pushed in the direction of the impact by an outer housing fastened to the damping member at least one location when the impact is applied on the fastened location.

9. The method of claim 8, wherein the damping member is composed of a particle-shaped foam resin having a density of 0.018 g/cm³ to 0.26 g/cm³, and the particle-shaped foam resin is composed of at least one of expanded polypropylene (EPP), expanded polyethylene (EPE), and expanded polyurethane (EPU).

10. The method of claim 8, wherein the relieving of the impact includes, in a state in which the outer housing is in close contact with the damping member at the fastened location, releasing the close contact when the impact is applied.

11. The method of claim 10, wherein the outer housing includes a fastening portion in which fastening is fixed by being engaged in a direction toward an inner housing of the damping member in a state in which the impact is not applied, and
the releasing of the close contact includes, when the inner housing is mounted in the damping member in a direction opposite to the outer housing and the impact is applied around the fastening portion, moving the fastening portion into a gap formed around a location where the fastening portion is fastened.

12. The method of claim 10, wherein the outer housing includes a hook member protruding toward the damping member and fastened to the damping member, and
the releasing of the close contact includes, when the impact is applied to the outer housing, moving the hook member in the direction of the impact as it compresses the damping member.

13. The method of claim 10, wherein an insertion groove of a predetermined size is formed in the damping member,
the outer housing includes an insertion member having a cross-sectional area of the predetermined size that is inserted into the insertion groove when fastened to the damping member, and
the releasing of the close contact includes:
when a washer having a cross-sectional area greater than the size of the insertion groove is fitted onto the insertion member, fixing the outer housing to the damping member by compressing the damping member against the washer and the outer housing; and
when the impact is applied to the outer housing, moving the insertion member and the washer in the direction of the impact by compressing the damping member by the insertion member.
